(19) United States
(12) Patent Application Publication
(10) Pub. No.: US 2004/0164417 A1
(43) Pub. Date: Aug. 26, 2004

(54) Semiconductor device and manufacturing method thereof

(75) Inventors: Yasunori Yamashita, Hyogo (JP); Kenichi Hatasako, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/642,170

(22) Filed: Aug. 18, 2003

(30) Foreign Application Priority Data
Feb. 20, 2003 (JP) 2003-042735(P)

(51) Int. Cl. H01L 23/48

(52) U.S. Cl. 257/758

(57) ABSTRACT

Interfaces between an Al alloy layer and a Ti-containing layer are present in a through hole formed between a lower layer interconnection and an upper layer interconnection. In the interfaces, resistance element regions are formed through heat treatment. A resistance value between the lower layer interconnection and the upper layer interconnection can be adjusted by means of the resistance element region.

### BACKGROUND OF THE INVENTION

1. Field of the Invention

The present invention relates to a semiconductor device and a manufacturing method thereof, and more particularly to a semiconductor device with a multi-layered interconnection structure having a through hole, and a manufacturing method thereof.

2. Description of the Background Art

In a conventional process for manufacturing a semiconductor device, an error in a resistance value of the order of 10% is usual even when a resistance of only several kΩ is formed. Therefore, in a semiconductor device in which high precision is demanded, a value for a resistance for adjustment has been controlled by a configuration in the following.

In a first configuration, a plurality of resistances connected in series are short-circuited by interconnections including polysilicon fuses respectively. The polysilicon fuse is blown by laser, in accordance with a resistance value required for adjustment. In this manner, the resistance that has been short-circuited by the polysilicon fuse is connected to a circuit. By adjusting the number of resistances connected to the circuit, a prescribed resistance value is obtained.

In a second configuration, zener diodes are connected in parallel, to respective resistances connected in series. An overvoltage is applied to a zener diode in accordance with the resistance value required for adjustment, and the zener diode is rendered conductive. In this manner, there is no current flow in the resistance connected to the zener diode that has been rendered conductive. By adjusting the number of resistances connected to the circuit as above, a prescribed resistance value is obtained.

On the other hand, Japanese Patent Laying-Open No. 8-125123 discloses a semiconductor device in which a portion of a metal interconnection layer formed on a semiconductor substrate serves as a resistance region. In this semiconductor device, the metal interconnection layer with a two-layered structure of Ti and Au is locally heated so as to increase the resistance value in that local portion, to form the resistance region.

In the semiconductor device as described above, a dedicated process for forming a polysilicon fuse or a zener diode for precision adjustment of a circuit is needed. In addition, in order to dispose the polysilicon fuse or the zener diode, an element area or an area for interconnection of the elements tends to increase, which will be a factor of a rise of the cost of the semiconductor device.

An object of the present invention is to provide a semiconductor device capable of adjusting a resistance value while suppressing an increase in an area thereof, as well as a method of manufacturing a semiconductor device.

### SUMMARY OF THE INVENTION

A semiconductor device according to the present invention includes: a lower layer interconnection; an upper layer interconnection; an interlayer insulating film having a through hole formed between the lower layer interconnection and the upper layer interconnection; and a conductive layer provided in the through hole, and electrically connecting the lower layer interconnection to the upper layer interconnection. An interface between an Al alloy layer and a Ti-containing layer is present in the through hole, and a resistance element region is provided in at least a portion of the interface.

A method of manufacturing a semiconductor device according to the present invention includes the steps of: forming a lower layer interconnection; forming an interlayer insulating film on the lower layer interconnection, and forming a through hole in the interlayer insulating film; forming on a surface of the interlayer insulating film and inside the through hole, a conductive layer including a Ti-containing layer fabricated with one or more layers selected from a Ti layer, a TiN layer, and a TiW layer, and an Al alloy layer adjacent to the Ti-containing layer, fabricated with one or more layers selected from an AlSiCu layer, an AlSi layer, and an AlCu layer; forming an upper layer interconnection by removing an unnecessary portion of the conductive layer; and subjecting the conductive layer in the through hole to heat treatment, to raise a resistance value between the lower layer interconnection and the upper layer interconnection.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1A is a plan view showing a structure of a semiconductor device in a first embodiment according to the present invention.

FIG. 1B is a vertical section showing the structure of the semiconductor device in the first embodiment according to the present invention.

FIG. 2 is a vertical section showing an enlarged view of a periphery of a through hole of the semiconductor device in the first embodiment according to the present invention.

FIGS. 3 to 11 are cross-sectional views showing first to ninth process steps in manufacturing the semiconductor device in the first embodiment according to the present invention.

FIG. 12 is a graph showing resistance values before and after heat treatment of the semiconductor device in the first embodiment according to the present invention.

FIG. 13 is a graph showing a difference in a rate of increase in the resistance value depending on a through hole diameter of the semiconductor device in the first embodiment according to the present invention.

FIGS. 14A to 14C are circuit diagrams in an example in which a conductive layer in the through hole of a semiconductor device is used for a precision adjustment unit in an IC circuit, in a second embodiment according to the present invention.

FIGS. 15A and 15B are circuit diagrams in an example in which the conductive layer in the through hole of a semiconductor device is used as a switching element, in a third embodiment according to the present invention.

FIG. 16 is a graph showing a current flow in an example in which the conductive layer in the through hole of the semiconductor device is, or is not, subjected to heat treatment, in the third embodiment according to the present invention.

FIGS. 17A and 17B are circuit diagrams in an example in which the conductive layer in the through hole of a semiconductor device is connected to a switching element, and used as a memory, in a fourth embodiment according to the present invention.

### DESCRIPTION OF THE PREFERRED EMBODIMENTS

### First Embodiment

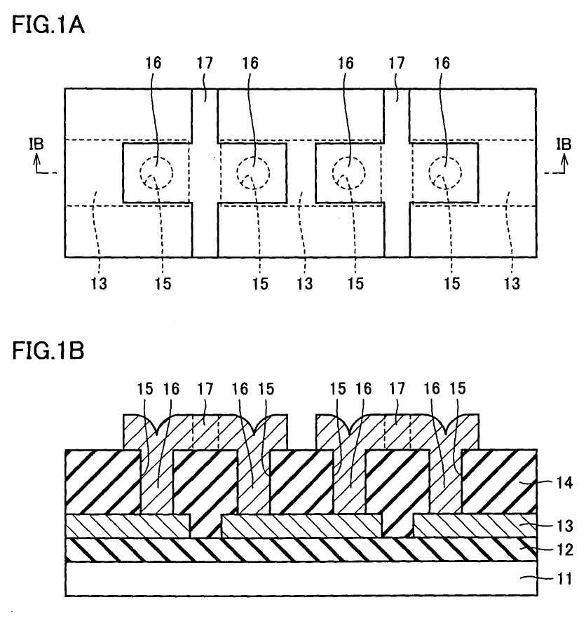

In the following, a semiconductor device and a manufacturing method thereof in the present embodiment will be described with reference to FIGS. 1A to 11.

(Structure of Semiconductor Device)

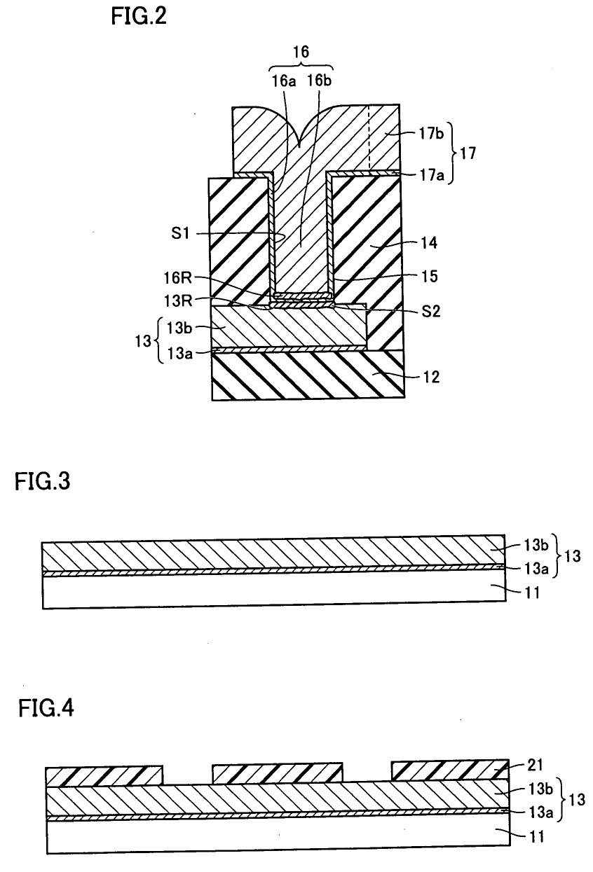

Referring to FIGS. 1A, 1B and 2, a structure of the semiconductor device will be described. As shown in FIG. 1B, a first interlayer insulating film 12 composed of SiO₂ is provided on a substrate 11 composed of Si. A lower layer interconnection 13 and a second interlayer insulating film 14 are provided on an upper surface of first interlayer insulating film 12. Lower layer interconnection 13 is formed with two layers as shown in FIG. 2, that is, a Ti layer 13a which is a Ti-containing layer deposited on first interlayer insulating film 12, and an AlSiCu layer 13b which is an Al alloy layer deposited on Ti layer 13a. Here, Ti layer 13a serves as a barrier metal layer.

Second interlayer insulating film 14 composed of SiO₂ is deposited on lower layer interconnection 13. A plurality of through holes 15 filled with a conductive layer 16 are provided in second interlayer insulating film 14. As shown in FIG. 2, an upper layer interconnection 17 is provided on the surface of second interlayer insulating film 14, so as to continue to conductive layer 16. Conductive layer 16 and upper layer interconnection 17 are constituted with Ti layers 16a, 17a, which are the Ti-containing layers, deposited on second interlayer insulating film 14, and AlSiCu layers 16b, 17b deposited thereon, which are the Al alloy layers, respectively. Ti layers 16a, 17a serve as a barrier metal layer. As can clearly be seen from FIG. 2, an interface S1 between Ti layer 16a which is the Ti-containing layer and AlSiCu layer 16b deposited on the surface thereof, which is the Al alloy layer, is present in through hole 15. Further, an interface S2 between Ti layer 16a and AlSiCu layer 13b which is the Al alloy layer of lower layer interconnection 13 is also present in through hole 15.

Conductive layer 16 disposed inside through hole 15 is provided so as to electrically connect lower layer interconnection 13 to upper layer interconnection 17. A resistance element region 16R formed through heat treatment and attaining a function as a resistance element is formed in interface S1 located in a bottom portion inside through hole 15. Resistance element region 16R is a region to increase the resistance value to a current that flows between conductive layer 16 in through hole 15 and lower layer interconnection 13. In addition, a resistance element region 13R formed through heat treatment is formed also in interface S2 located in a lowermost portion inside through hole 15.

AlSiCu layers 13b, 16b, 17b can be fabricated with the Al alloy layer, and may be fabricated, for example, with an AlSi layer or an AlCu layer. Alternatively, a combination of these layers is possible. Ti layers 13a, 16a, 17a can be fabricated with the Ti-containing layer, and may be fabricated, for example, with a TiW layer or a layer composed of TiN and Ti. Alternatively, a combination of these layers is possible.

(Manufacturing Method of Semiconductor Device)

A method of manufacturing a semiconductor device will be described with reference to FIGS. 3 to 11. In the semiconductor device described above, lower layer interconnection 13 is provided on substrate 11 with first interlayer insulating film 12 interposed. On the other hand, in an example described here, lower layer interconnection 13 is provided directly on substrate 11 so as to attain contact therebetween.

Referring to FIG. 3, Ti layer 13a and AlSiCu layer 13b serving as lower layer interconnection 13 are deposited on substrate 11 composed of Si. Ti layer 13a is deposited to a film thickness of approximately 500 Å, and subjected to lamp anneal at approximately 800° C. Thereafter, AlSiCu layer 13b is deposited to a film thickness of approximately 5000 Å. Here, a not-shown anti-reflection coating composed of Si, TiN or the like is formed on the surface of AlSiCu layer 13b for preventing reflection.

Referring to FIG. 4, a resist film 21 in a pattern of lower layer interconnection 13 is formed on AlSiCu layer 13b with photolithography. Referring to FIG. 5, Ti layer 13a and AlSiCu layer 13b are subjected to dry etching so as to form lower layer interconnection 13.

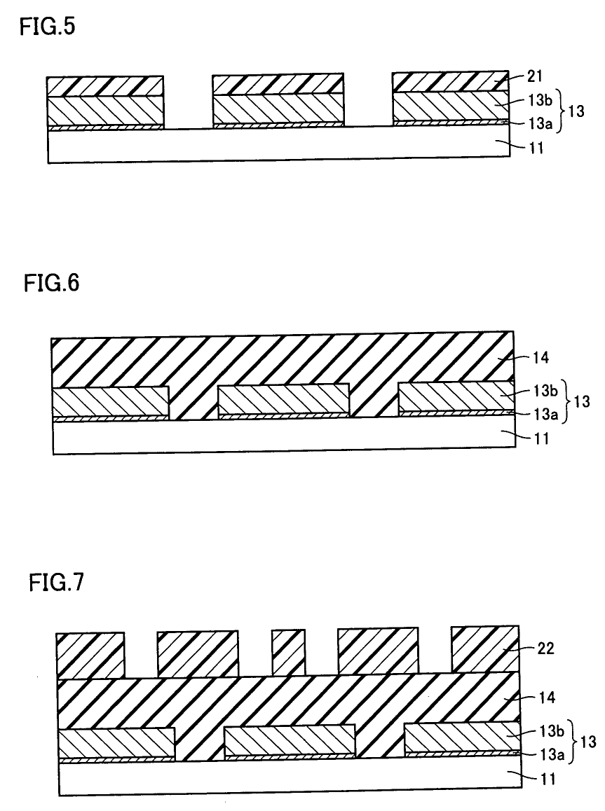

Referring to FIG. 6, after resist film 21 is removed, interlayer insulating film 14 is deposited, so as to ensure insulation between upper layer interconnection 17, which will be formed later, and lower layer interconnection 13. Here, as a difference of height between substrate 11 and lower layer interconnection 13 is large, an SOG (Spin On Glass) film is employed as interlayer insulating film 14 so as to fill such a stepped portion. The film thickness of interlayer insulating film 14 on lower layer interconnection 13 is set approximately to 1 μm.

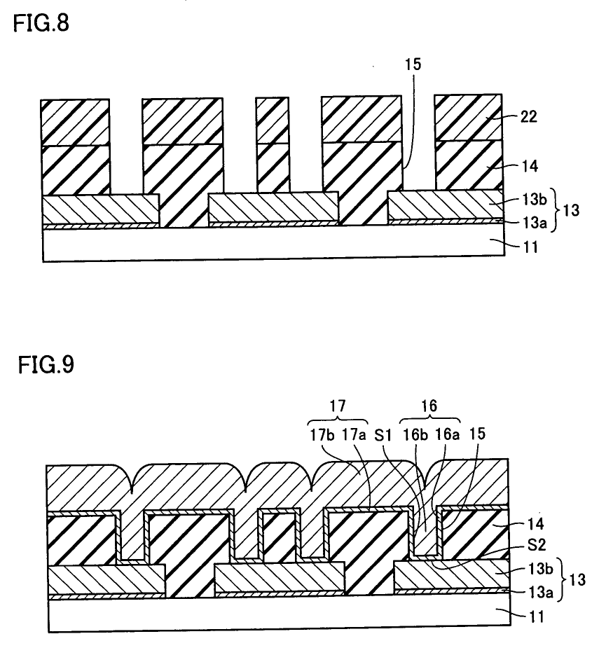

Referring to FIG. 7, a resist film 22 in a pattern of the through hole is formed on the surface of interlayer insulating film 14 with photolithography. Referring to FIG. 8, through hole 15 is formed by wet etching and dry etching.

After resist film 22 is removed, referring to FIG. 9, Ti layers 16a, 17a and AlSiCu layers 16b, 17b which will serve as conductive layer 16 and upper layer interconnection 17 are deposited. On interlayer insulating film 14, the film thickness of Ti layers 16a, 17a attains to approximately 500 Å, while the film thickness of AlSiCu layers 16b, 17b attains to approximately 1 μm. Here, interface S1 between Ti layer 16a, which is the Ti-containing layer, and AlSiCu layer 16b deposited on the surface thereof, which is the Al alloy layer, is present in through hole 15. Further, interface S2 between Ti layer 16a and AlSiCu layer 13b which is the Al alloy layer of lower layer interconnection 13 is also present in the lowermost portion in through hole 15.

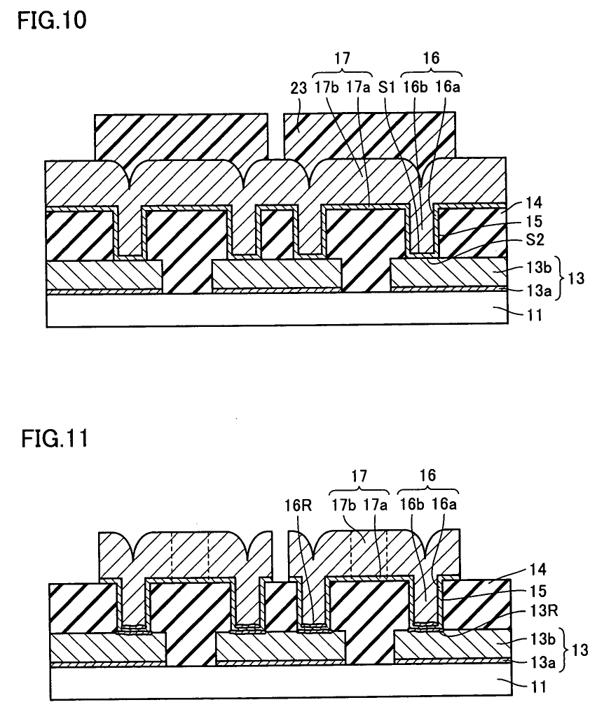

Referring to FIG. 10, a resist film 23 in a pattern of upper layer interconnection 17 is deposited on AlSiCu layers 16b, 17b. Referring to FIG. 11, an unnecessary portion of Ti layers 16a, 17a and AlSiCu layers 16b, 17b is removed by dry etching, to form upper layer interconnection 17, followed by removal of resist film 23.

Finally, conductive layer 16 in through hole 15 is irradiated with a laser beam from above in FIG. 11 for heat treatment. In this manner, resistance element region 16R is formed in interface Si within conductive layer 16, while resistance element region 13R is formed in interface S2 between conductive layer 16 and lower layer interconnection 13. The resistance value between upper layer interconnection 17 and lower layer interconnection 13 is thus raised. A heating temperature at this time is set to 450° C. If the resistance value only of conductive layer 16 in at least one of through holes 15 is raised, an apparatus capable of applying heat in a pinpointed manner, such as laser, is used to attain local heating. On the other hand, if the resistance value of conductive layer 16 in every through hole 15 is raised, an entire surface of substrate 11 may be heated, for example, with a baking furnace.

In interfaces S1, S2 in through hole 15 that was subjected to heat treatment at 450° C., the Al alloy layer and the Ti-containing layer are located adjacent to each other. Therefore, precipitation of Si crystal or aggregation of Ti takes place, to form resistance element regions 13R, 16R as shown in FIGS. 2 and 11. As a result, the resistance value locally increases, and accordingly, the resistance value between lower layer interconnection 13 and upper layer interconnection 17 that are connected by conductive layer 16 in through hole 15 is raised, to attain a function as resistance.

Here, interface S1 between the Al alloy layer and the Ti-containing layer is present also in a position along an inner face of through hole 15. When conductive layer 16 inside through hole 15 is heated, in some cases, the resistance element region is formed also in that position of interface S1. The resistance element region formed along the inner face of through hole 15 usually does not function as the resistance between lower layer interconnection 13 and upper layer interconnection 17, though depending on a diameter of through hole 15 or a required resistance value. In addition, even if the resistance element region is formed along the inner face of through hole 15 in such a manner, this will not present an obstacle.

In order to increase the resistance between lower layer interconnection 13 and upper layer interconnection 17, the resistance element region is desirably formed so as to intersect a current flowing between lower layer interconnection 13 and upper layer interconnection 17. In the present embodiment, resistance element regions 13R, 16R extending two-dimensionally in the bottom portion and the lowermost portion of through hole 15 are formed as described above. As resistance element regions 13R, 16R are formed so as to intersect the current flowing between lower layer interconnection 13 and upper layer interconnection 17, these regions serve as resistance elements effective for the current flowing.

In order to form resistance element regions 13R, 16R in the bottom portion and the lowermost portion of conductive layer 16 in through hole 15 in this manner, in the present embodiment, conductive layer 16 is irradiated with a laser beam from above for heating. The laser beam, however, may be applied from a different direction, depending on a structure of layers, or a shape of through hole 15. For example, the laser beam maybe applied from the lower side of substrate 11 for heating.

In addition, through hole 15 may be formed with a small depth, so that the bottom portion and the lowermost portion of conductive layer 16 in through hole 15 are easily heated when conductive layer 16 is irradiated with the laser beam from above. For example, depth of through hole 15 may be smaller than the diameter thereof.

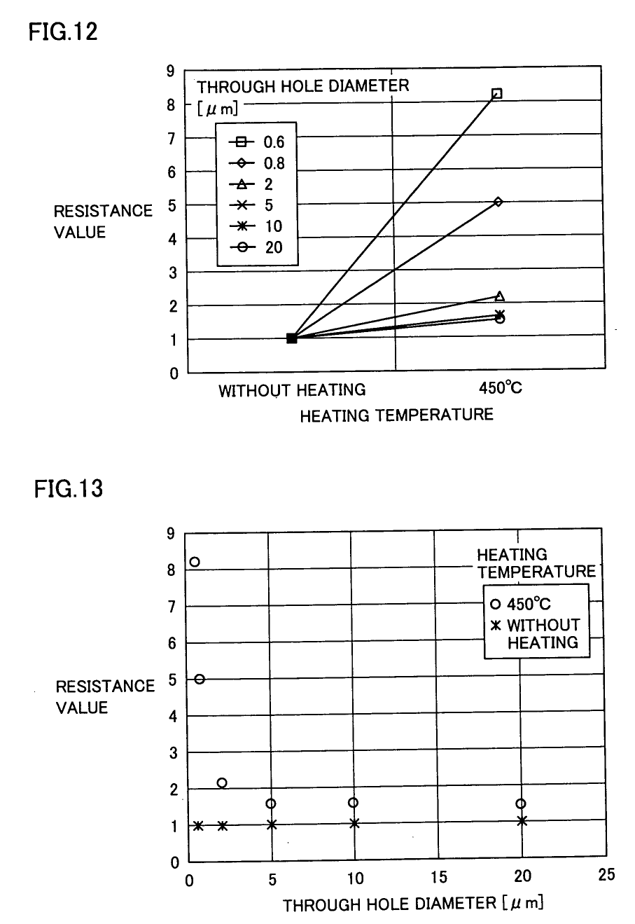

FIG. 12 shows a change in the resistance value, in an example where heat treatment at 450° C. is performed, and in an example without heat treatment. Here, FIG. 12 shows the resistance value in an example where the heat treatment at 450° C. is performed, in a through hole chain where 16 to 3400 through holes are connected, assuming that the resistance value when heat treatment is not performed attains to 1. As can clearly be seen from FIG. 12, the resistance value is raised through heat treatment at 450° C.

A rate of increase in the resistance value is different, dependent on the diameter of through hole 15. As can be seen from FIG. 13, the smaller the diameter of through hole 15 is, the larger the resistance value is. Particularly, when the diameter of through hole 15 is not larger than 0.8 μm, the increase in the resistance value is remarkable. Therefore, in order to remarkably change the resistance value before and after the heat treatment, through hole 15 preferably has a diameter of not smaller than 0.4 μm, that is, an effectively manufacturable size, and not larger than 0.8 μm.

In addition, a temperature for heat treatment should be higher than the heating temperature during a wafer manufacturing process, and preferably, it is set to not lower than 350° C. and not higher than 600° C. In other words, in order to leave a margin for local increase in the resistance value by further heating in a subsequent heat treatment, the heating temperature in the wafer manufacturing process should be set to a relatively low temperature (not higher than 300° C., for example). If the temperature for the heat treatment is less than 350° C., the resistance value is not sufficiently raised. On the other hand, if the temperature for the heat treatment exceeds 600° C., components in the semiconductor device may adversely be affected.

In the present embodiment, conductive layer 16 in through hole 15 is constituted with two layers of AlSiCu layer 16b and Ti layer 16a, and thus, interface S1 between the Al alloy layer and the Ti-containing layer is formed. Further, an uppermost layer of lower layer interconnection 13 is fabricated with AlSiCu layer 13b, whereby, interface S2 between the Al alloy layer and the Ti-containing layer is formed also between conductive layer 16 and lower layer interconnection 13. The interface between the Al alloy layer and the Ti-containing layer, however, is not necessarily formed in such a manner as in the present embodiment, and the interface may be provided only in conductive layer 16 in through hole 15. For example, conductive layer 16 in through hole 15 is entirely fabricated with the Al alloy layer, and the uppermost layer of lower layer interconnection 13 is fabricated with the Ti-containing layer, which are in turn brought in contact in the lowermost portion of through hole 15. The interface between the Al alloy layer and the Ti-containing layer may thus be formed only in the lowermost portion of through hole 15. The resistance element region is formed in the interface through the heat treatment as described above. Therefore, the interface should exist in such a position that the resistance element region would raise the resistance value between upper layer interconnection 17 and lower layer interconnection 13. Further, another thin layer which does not prevent formation of the resistance element region may be included in the interface.

As described above, in the semiconductor device in the present embodiment, local or entire heat treatment is performed after the element is formed (after the wafer manufacturing process) so as to form the resistance element region in the interface in the through hole, which in turn can increase the resistance value between the lower layer interconnection and the upper layer interconnection. An application example of the semiconductor device in the present embodiment utilizing this property will be described in the following.

### Second Embodiment

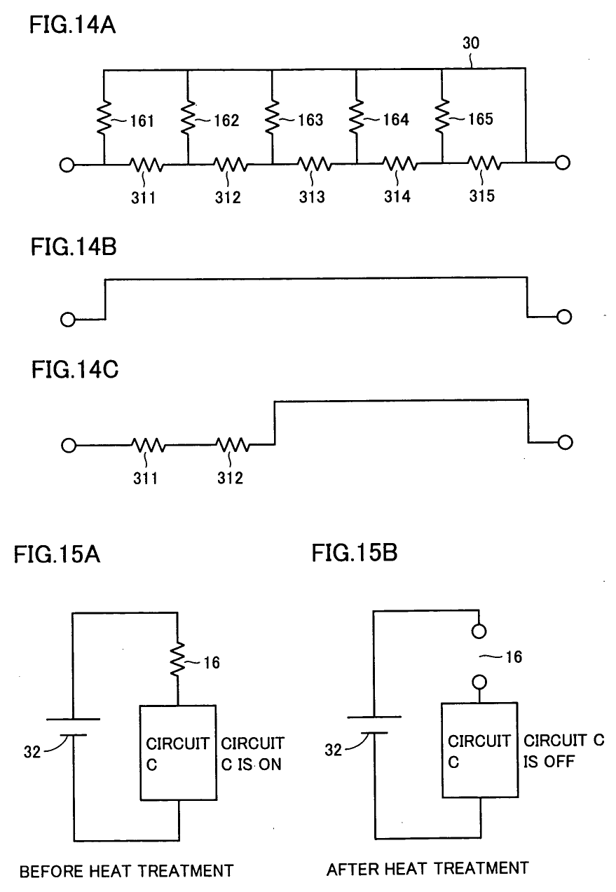

The present embodiment will be described with reference to FIGS. 14A to 14C. In the present embodiment, as shown in FIG. 14A, five load resistance elements 311 to 315 connected in series, and a bypass line 30 connected to a rear end portion of load resistance element 315 at a rear end are provided in a precision adjustment unit of an IC circuit. Conductive layers 161 to 165 in through hole 15 are arranged so as to connect a tip end portion of load resistance element at a tip end and connection portions between load resistance elements 311 to 315 to bypass line 30. In FIG. 14A, conductive layers 161 to 165 are represented as resistance.

If none of conductive layers 161 to 165 is subjected to heat treatment, a short-circuited state in which a current flows through bypass line 30 is exhibited, as shown in FIG. 14B. Here, for example, if conductive layers 161 and 162 are subjected to heat treatment so as to increase the resistance value thereof, a state shown in FIG. 14C is exhibited. In other words, the current flows through load resistance elements 311 and 312, and by means of the resistance of these load resistance elements, fine adjustment in precision of the IC circuit can be attained.

As described above, a circuit conventionally constituted with a polysilicon fuse can be fabricated with conductive layer 16 in through hole 15. In other words, by selecting only a conductive layer of which resistance value should be increased, and heating that conductive layer in a pinpointed manner after the semiconductor element is formed, an effect similar to polysilicon fuse blow (a circuit that has been connected is brought into an “OPEN” state) can be obtained.

In addition, a dedicated wafer process is not necessary for forming through hole 15 and conductive layer 16. Therefore, addition of a process step as in an example where the polysilicon fuse is provided is not necessary. Moreover, the element attaining an effect similar to the polysilicon fuse can be fabricated in a size of through hole 15. Thus, as the area for the semiconductor device hardly increases, cost lower than in a conventional configuration can be achieved.

The present embodiment may be modified so that conductive layers 16 in through holes 15 instead of the load resistance element are connected in series. In other words, conductive layer 16 in through hole 15 may be configured as a variable resistance, so as to attain fine adjustment in precision of the IC circuit. In such a case, by controlling the number of conductive layers 16 to be subjected to heat treatment, as well as the diameter of through hole 15 for conductive layer 16, an arbitrary resistance value can be obtained.

### Third Embodiment

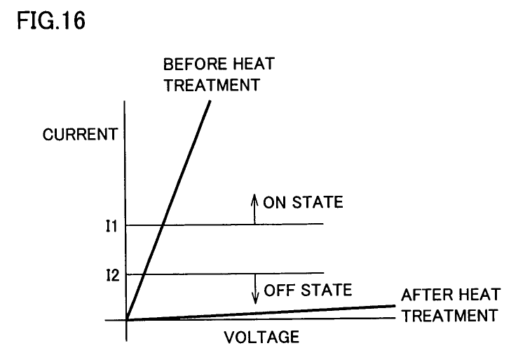

A semiconductor device in the present embodiment will be described with reference to FIGS. 15A to 16. In the present embodiment, as shown in FIGS. 15A and 15B, a circuit C detecting the current flowing in conductive layer 16 and connecting or disconnecting a power supply 32 is connected to conductive layer 16 in through hole 15. Here, conductive layer 16 is represented as resistance.

Before conductive layer 16 is subjected to heat treatment, the resistance value thereof is small, and therefore, there is a large current flow, as shown in FIG. 16. On the other hand, after conductive layer 16 is subjected to heat treatment, the resistance value thereof will be large, and there is almost no current flow. The circuit C connected to conductive layer 16 is configured so as to be turned ON when the current not smaller than a current value of I1 flows, and to be turned OFF when the current not larger than a current value of I2 flows.

Accordingly, before heat treatment, a large current exceeding current value I1 flows in conductive layer 16 as shown in FIG. 15A, and circuit C enters an ON state. On the other hand, after heat treatment, there is almost no current flow in conductive layer 16 as shown in FIG. 15B, and therefore, the current value attains not larger than I2, and circuit C enters an OFF state. By connecting such a circuit C to conductive layer 16, conductive layer 16 in through hole 15 shown in the first embodiment can be used as a switching element capable of selecting ON or OFF, after the wafer manufacturing process ends.

### Fourth Embodiment

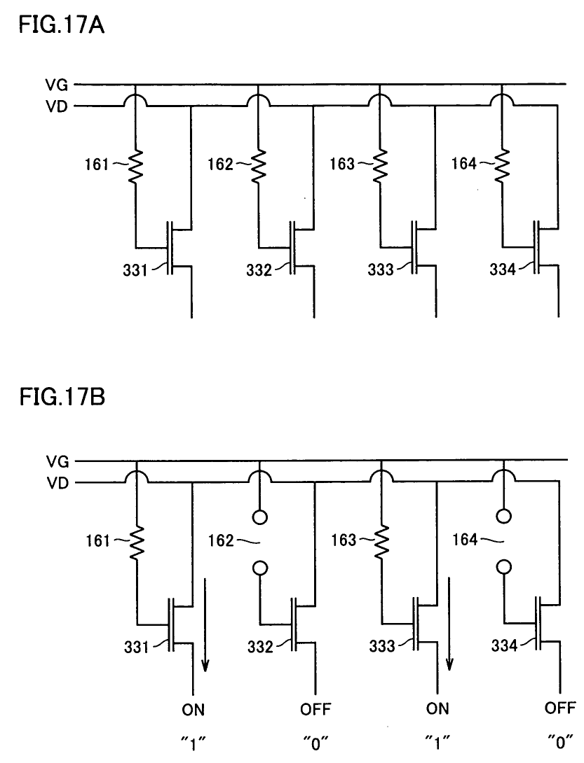

The present embodiment will be described with reference to FIGS. 17A and 17B. As shown in FIG. 17A, conductive layers 161 to 164 in through hole 15 are connected to the gate electrodes of transistors as switching elements 331 to 334 respectively. Here, conductive layers 161 to 164 are represented as resistance.

For example, among four conductive layers 161 to 164 shown in FIG. 17A, only conductive layers 162, 164 are subjected to heat treatment, so as to increase the resistance value. In doing so, as shown in FIG. 17B, almost no current flows through switching elements 332, 334, and these switching elements enter the OFF state. On the other hand, the current flows through switching elements 331, 333 connected to conductive layers 161, 163 which have not been subjected to heat treatment, and these switching elements enter the ON state. Consequently, signals from these four switching elements 331 to 334 attain ON, OFF, ON, and OFF respectively, and “1”, “0”, “1”, and “0” are output respectively. In this manner, by selectively subjecting conductive layers 161 to 164 to heat treatment, the conductive layer can be applied as a memory providing ON/OFF (1/0) control.

In the present embodiment, though conductive layers 161 to 164 in the through holes are connected to the gate electrodes of the transistors as switching elements 331 to 334 respectively, conductive layers 161 to 164 in the through holes may be connected to drain electrodes respectively. With such connection, selection of ON or OFF of a voltage applied to the drain electrode of the transistor is allowed, and thus, ON/OFF control of a signal output from the transistor can be achieved.

As described above, the semiconductor device in the present embodiment can adjust the resistance value while suppressing increase in the area of the semiconductor device.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device, comprising:
a lower layer interconnection;
an upper layer interconnection;
an interlayer insulating film having a through hole formed between said lower layer interconnection and said upper layer interconnection; and
a conductive layer provided in said through hole, and electrically connecting said lower layer interconnection to said upper layer interconnection; wherein
an interface between an Al alloy layer and a Ti-containing layer is present in said through hole, and
a resistance element region is provided in at least a portion of said interface.

2. The semiconductor device according to claim 1, wherein
said resistance element region in said through hole is formed by subjecting said conductive layer in said through hole to heat treatment.

3. The semiconductor device according to claim 1, wherein
said Al alloy layer includes at least one layer selected from an AlSiCu layer, an AlSi layer and an AlCu layer, and
said Ti-containing layer includes at least one layer selected from a Ti layer, a TiN layer, and a TiW layer.

4. The semiconductor device according to claim 1, wherein
a plurality of through holes are provided, and said resistance element region is provided in said interface in selected at least one of said through holes.

5. The semiconductor device according to claim 1, wherein
said resistance element region is provided in said interface in every said through hole.

6. The semiconductor device according to claim 1, wherein
said through hole has a diameter of at least 0.4 μm and at most 0.8 μm.

7. The semiconductor device according to claim 1, further comprising a plurality of load resistance elements connected in series, and a bypass line connected to a rear end portion of the load resistance element at a rear end, wherein
the conductive layer of the through hole is disposed so as to connect a tip end portion of the load resistance element at a tip end and a connection portion between load resistance elements to the bypass line.

8. The semiconductor device according to claim 1, wherein
said conductive layer in said through hole is connected to a circuit detecting a current which flows in said conductive layer, and connecting or disconnecting a power supply.

9. The semiconductor device according to claim 1, wherein
said conductive layer in said through hole is connected to a switching element.

10. A method of manufacturing a semiconductor device, comprising the steps of:
forming a lower layer interconnection;
forming an interlayer insulating film on said lower layer interconnection, and forming a through hole in the interlayer insulating film;
forming on a surface of said interlayer insulating film and inside the through hole, a conductive layer including a Ti-containing layer fabricated with at least one layer selected from a Ti layer, a TiN layer, and a TiW layer, and an Al alloy layer adjacent to said Ti-containing layer, fabricated with at least one layer selected from an AlSiCu layer, an AlSi layer and an AlCu layer;
forming an upper layer interconnection by removing an unnecessary portion of said conductive layer; and
subjecting said conductive layer in said through hole to heat treatment, to raise a resistance value between said lower layer interconnection and said upper layer interconnection.

11. The method of manufacturing a semiconductor device according to claim 10, wherein
a heating temperature during said heat treatment is set to at least 350° C.

12. The method of manufacturing a semiconductor device according to claim 10, wherein
said heat treatment is performed by selecting a conductive layer in a through hole, of which resistance value should be increased, and irradiating the conductive layer with a laser beam.
